(19) United States
(12) Patent Application Publication
(10) Pub. No.: US 2007/0020904 A1
(43) Pub. Date: Jan. 25, 2007

(54) Selectively filling microelectronic features

(76) Inventor: Michael E. Stora, Maricopa, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/182,612

(22) Filed: Jul. 15, 2005

(51) Int. Cl. H01L 21/44

(52) U.S. Cl. 438/597

(57) ABSTRACT

Some embodiments of the present invention include filling features using selective fill techniques.

### TECHNICAL FIELD

Embodiments of the invention relate to electronics fabrication. In particular, embodiments of the invention relate to methods and apparatus for fabricating conductive features in a substrate.

### BACKGROUND

Integrated circuits (ICs) and printed circuit boards (PCBs) typically include circuit components connected by conductive features, such as lines and vias. Conductive lines may be formed by providing a trench in a substrate and filling the trench with a conductive material, typically a metal. Similarly, vias may be formed by providing a hole in a substrate and filling the hole with a conductive material, typically a metal.

Filling the trench or hole may provide numerous challenges, particularly when the feature is deep or has a high aspect ratio (the ratio of the depth of a feature to the width of the feature). In conventional fill technologies, undesirable voids may be created in the conductive features that may lead to performance problems or device failure.

### BRIEF DESCRIPTION OF THE DRAWINGS

The invention is illustrated by way of example and not by way of limitation in the figures of the accompanying drawings, in which the like references indicate similar elements and in which:

FIGS. 1A-1F illustrate cross sectional type views of a method in accordance with one embodiment of the present invention.

FIG. 2 illustrates a block diagram of a system in accordance with one embodiment of the present invention.

### DETAILED DESCRIPTION

In various embodiments, an apparatus and method relating to filling features in a substrate are described. In the following description, various embodiments will be described. However, various embodiments may be practiced without one or more of the specific details, or with other methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Various operations will be described as multiple discrete operations in turn. However, the order of description should not be construed as to imply that these operations are necessarily order dependent. In particular, these operations need not be performed in the order of presentation.

In order to fill features, such as lines or vias, without voids, selective fill techniques may be used. Further, selective filling of features may be simpler, less expensive, and faster than existing technologies. Selective filling of features may also provide a simple solution for filling features having different shapes or aspect ratios using the same processing steps.

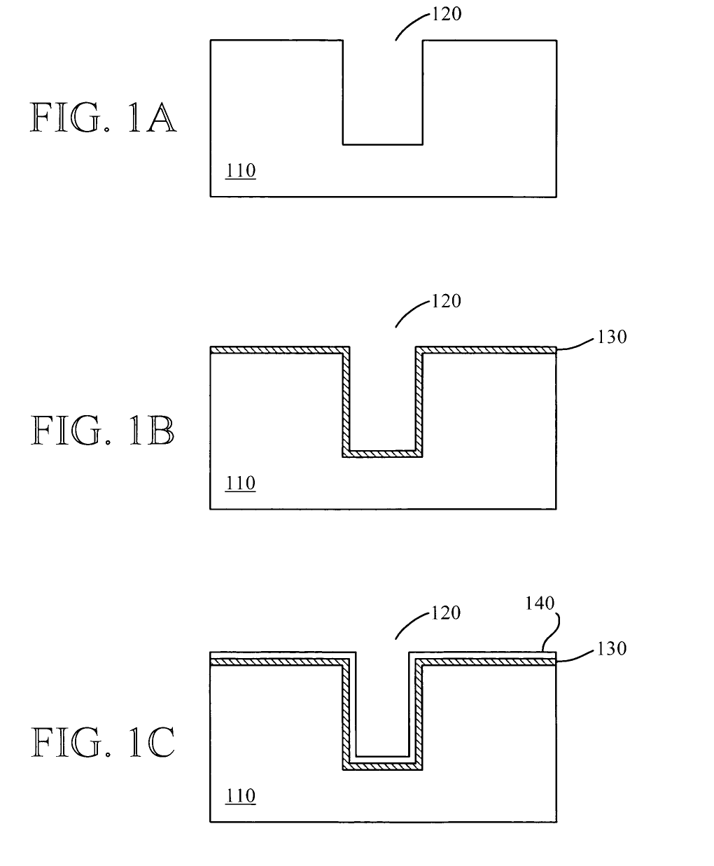

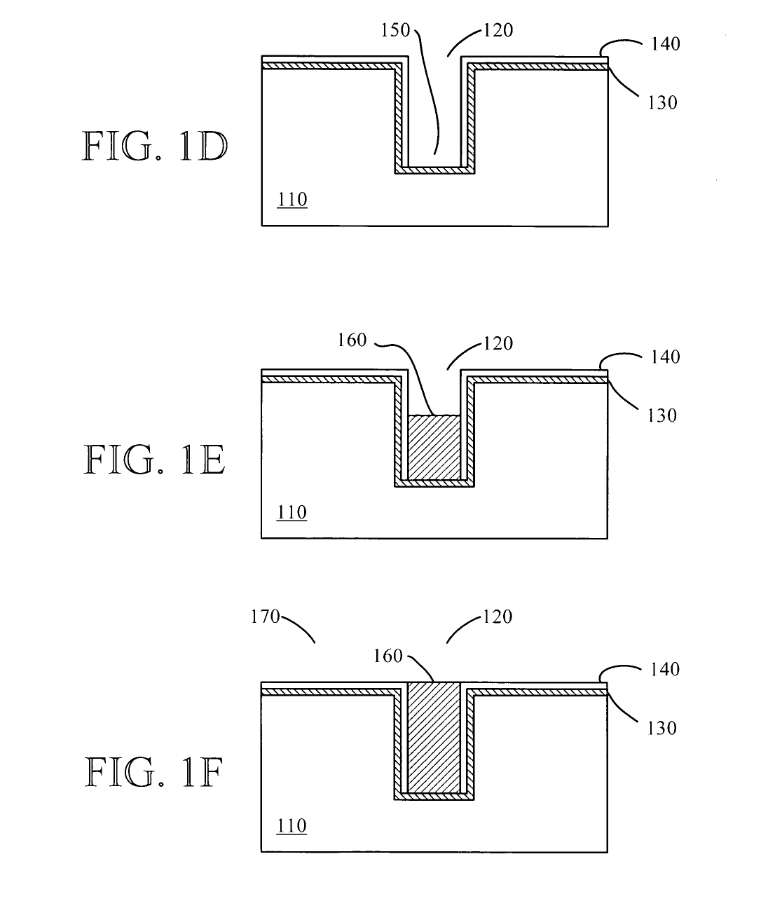

FIGS. 1A-1F illustrate cross-sectional type views of a method for selective filling of features in accordance with an embodiment of the present invention.

FIG. 1A illustrates a substrate 110 and a feature 120. Substrate 110 may be any suitable material. In an embodiment, substrate 110 may include Silicon. In another embodiment, substrate 110 may include an interlayer dielectric (ILD). In other embodiments, substrate 110 may include a variety of conductive, insulative, and semiconductor materials and a variety of structures including metallization layers, transistors, resistors, and others. In an embodiment, substrate 110 may be a printed circuit board (PCB).

Feature 120 may be formed in substrate 110 by any suitable technique, such as conventional lithography and etch techniques. Feature 120 may be of any suitable shape and size. In an embodiment, feature 120 may have a shape such that from a top down view, feature 120 is substantially round or oval in shape. In such embodiments, feature 120 may be referred to as a via, a contact, or a hole. In another embodiment, feature 120 may have a shape such that from a top down view, feature 120 is substantially linear. In such embodiments, feature 120 may be referred to as a line or trench.

In cross section, feature 120 may also be of any suitable shape. In an embodiment, feature 120 may include side walls that are substantially vertical and the top and the bottom of feature 120 may be substantially the same size. In another embodiment, the top of feature 120 may be larger than the bottom of feature 120 and the side walls may angle from the top to the bottom of feature 120. In some embodiments, feature 120 may have a bottom that is substantially flat. In other embodiments, feature 120 may have a bottom that is curved. Many other variations on the shape of feature 120 may be available.

Feature 120 may have any aspect ratio (the ratio of the depth of a feature to the width of the feature). In an embodiment, feature 120 may have an aspect ratio that is greater than 4. In another embodiment, feature 120 may have an aspect ratio in the range of about 4 to 12. In an embodiment, feature 120 may have an aspect ratio in the range of about 8 to 20.

Only one feature 120 is shown in FIGS. 1A-1F for the sake of simplicity; however, substrate 110 may include any number of features and features of any variety. In an embodiment, both lines and vias may be included in substrate 110. In another embodiment, lines having different aspect ratios may be included in substrate 110. In embodiments including a majority of line features, the line features together may be generally referred to as a metallization layer. In an embodiment, vias having different aspect ratios may be included in substrate 110. In embodiments including a majority of via features, the line features together may be generally referred to as a via layer or a contact layer.

As shown in FIG. 1B, a seed layer 130 may be formed over substrate 110 and feature 120. Seed layer 130 may be any suitable material and may be formed by any suitable technique. In an embodiment, seed layer 130 may be formed by a sputtering process. In some embodiments, an adhesion layer (or several adhesion layers) may be deposited prior to forming seed layer 130. In an embodiment, seed layer 130 may include a conductive material. In an embodiment, seed layer 130 may include a metal. In an embodiment, seed layer 130 may include Copper. As is further discussed below, seed layer 130 may provide a site for providing a fill into feature 120.

As illustrated in FIG. 1C, a barrier layer 140 may be formed over seed layer 130. Barrier layer 140 may be any suitable material and may be formed by any suitable technique. As is further discussed below, barrier layer 140 may prohibit a fill material from forming on the surface of barrier layer 140. In an embodiment, barrier layer 140 may be formed by chemical vapor deposition (CVD). In another embodiment, barrier layer 140 may be formed using a sputter technique. In some embodiments, an adhesion layer (or several adhesion layers) may be provided prior to forming barrier layer 140. In an embodiment, barrier layer 140 may include an insulating material.

As illustrated in FIG. 1D an opening 150 may be created in barrier layer 140 by removing a portion of barrier layer 140. Opening 150 may be created by any suitable technique. In an embodiment, opening 150 may be created using an isotropic etch technique. In an embodiment, opening 150 may be created using an isotropic etch technique and the thickness of insulting layer 140 in feature 120 may be less than the thickness of barrier layer 140 over the remainder of substrate 110 such that the isotopic etch creates opening 150 in feature 120, but does not create openings above the remainder of substrate 110. In another embodiment, opening 150 may be created using a mask process and an isotropic etch. In an embodiment, the mask process may include lithography. In an embodiment, the mask process may leave feature 120 exposed and cover the rest of barrier layer 140 during the etch step. In an embodiment, if an adhesion layer (or several adhesion layers) were used in forming barrier layer 140, an etch technique may be used to remove the adhesion layer (or layers). Opening 150 may be created in any suitable location. In an embodiment, opening 150 may be created at the bottom of feature 120.

As illustrated in FIG. 1E, a fill material 160 may be formed in feature 120. Fill material 160 may be formed by any suitable technique and may include any suitable material. In an embodiment, fill material may be formed using the exposed portion of seed layer 130. In such embodiments, there may be no (or little) risk that fill material 160 may pinch off and form a void in feature 120 because fill material 160 is being formed from only one surface. In an embodiment, fill material 160 may be formed by electroplating. In another embodiment, fill material 160 may be formed by electroless plating. In an embodiment, seed layer 130 may be a conductor, barrier layer 140 may be an insulator, fill material 160 may be formed by electroplating or electroless plating, and fill material 160 may form from the bottom to the top of feature 120. In an embodiment, fill material 160 may include Copper.

As illustrated in FIG. 1F, a filled feature 170 may be formed. In an embodiment, filled feature 170 may be formed by continuing the fill process illustrated in FIG. 1E. In another embodiment, forming filled feature 170 may include filling feature 120 over the surface of barrier layer 140 and polishing the fill material 160 back to the level of the surface of barrier layer 140. In an embodiment, polishing the fill material may include a chemical mechanical polishing (CMP) process. In an embodiment, filled feature 170 may be a conductor. In another embodiment, filled feature 170 may include a metal. In an embodiment, filled feature 170 may include Copper.

In some embodiments, filled feature 170 may provide electrical connections within a semiconductor device. In an embodiment the semiconductor device may be a microprocessor. In other embodiments, the semiconductor device may be a memory controller hub, input/output (I/O) controller hub, graphics processor, display processor, network processor, or network interface component. In yet other embodiments, the semiconductor device may be a volatile memory component such as a dynamic random access memory or a static random access memory.

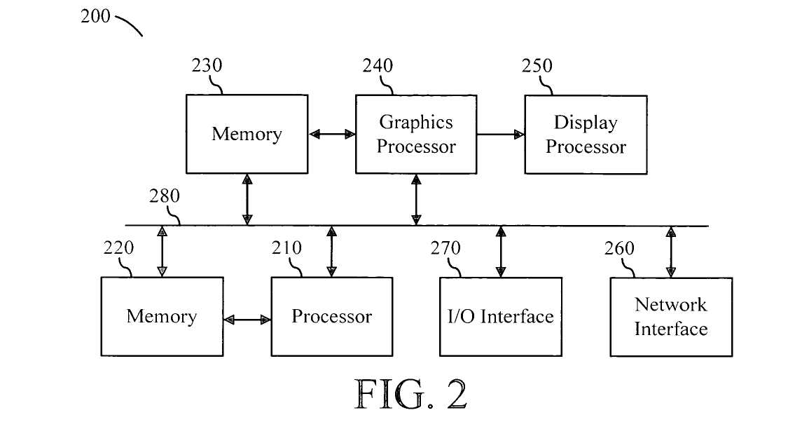

As illustrated in FIG. 2, filled feature 170 may be incorporated into a system 200. System 200 may include a processor 210, a memory 220, a memory 230, a graphics processor 240, a display processor 250, a network interface 260, an I/O interface 270, and a communication bus 280. As discussed, any of the components in system 200 may include filled feature 170. In an embodiment, processor 210 may include filled feature 170. In another embodiment, graphics processor 240 may include filled feature 170. A large number of combinations of components including filled feature 170 may be available.

Reference throughout this specification to “one embodiment” or “an embodiment” means that a particular feature, structure, material, or characteristic described in connection with the embodiment is included in at least one embodiment of the invention. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. A method comprising:
providing a seed layer over a feature in a substrate;
forming a barrier layer over the seed layer;
removing a portion of the barrier layer to expose a portion of the seed layer; and
forming a fill material in the feature, wherein the fill material forms at the exposed portion of the seed layer.

2. The method of claim 1, wherein the feature comprises a via.

3. The method of claim 1, wherein the feature comprises a trench.

4. The method of claim 1, wherein the feature comprises a feature having an aspect ratio in the range of about 8 to 20.

5. The method of claim 1, wherein removing a portion of the barrier layer includes removing a portion of the barrier layer at a bottom of the feature.

6. The method of claim 5, wherein the barrier layer includes an insulating material and forming the fill material includes electroplating the fill material from the bottom of the feature.

7. The method of claim 1, wherein the seed layer includes Copper and forming the fill material includes electroless plating.

8. The method of claim 1, wherein removing the portion of the barrier layer includes an isotropic etch process.

9. The method of claim 1, wherein removing the portion of the barrier layer includes a masked etch process.

10. The method of claim 1, wherein the seed layer includes a conductive material, the barrier layer includes an insulating material, and forming the fill material includes electroplating the fill material in the feature.

11. The method of claim 10, further comprising:
polishing the fill material using a chemical mechanical polishing process.

12. The method of claim 10, wherein the seed layer and the fill material include Copper.

13. An apparatus comprising:
a conductive seed layer over a feature in a substrate;
a conductive fill material in the feature and in contact with the seed layer; and
an insulating layer in the feature between the fill material and the seed layer.

14. The apparatus of claim 13, wherein the conductive fill material is in contact with the conductive seed layer at the bottom of the feature.

15. The apparatus of claim 13, wherein the feature is a via.

16. The apparatus of claim 13, wherein the feature has an aspect ratio in the range of about 8 to 20.

17. The apparatus of claim 13, further comprising:
a second feature in the substrate, wherein the seed layer is over the second feature and the second feature and the feature have different aspect ratios;
a second conductive fill material in the second feature and in contact with the seed layer; and
a second insulating layer in the second feature between the fill material and the seed layer.

18. The apparatus of claim 17, wherein the first and second features are vias.

19. The apparatus of claim 17, wherein the first feature is a via and the second feature is a line.

20. A system comprising:
a microprocessor including
a conductive seed layer over a feature in a substrate;
a conductive fill material in the feature and in contact with the seed layer;
an insulating layer in the feature between the fill material and the seed layer; and
a display processor.

21. The system of claim 20, further comprising:
a volatile memory component.
